(19) United States
(12) Patent Application Publication
(10) Pub. No.: US 2023/0358822 A1
(43) Pub. Date: Nov. 9, 2023

(54) Electrical system comprising a redundant electrical transmission path and means for recognizing an error state thereof, and method for recognizing an error state of the redundant electrical transmission path of the electrical system

(71) Applicant: IMS GEAR SE & CO. KGAA, Donaueschingen (DE)

(72) Inventor: Daniel REHLE, Niedereshach (DE)

(21) Appl. No.: 18/142,839

(22) Filed: May 3, 2023

(30) Foreign Application Priority Data
May 3, 2022 (EP) 22171379.5

(51) Int. Cl. G01R 31/50; G01R 27/26

(52) U.S. Cl. CPC G01R 31/50; G01R 27/2611

(57) ABSTRACT

An electrical system includes a first electrical device, a second electrical device, a redundant electrical transmission path having two electrical connecting lines, connected in parallel, between the two electrical devices, and means for recognizing an error state of the redundant electrical transmission path). The means encompass a magnetic core having a primary conductor including at least half a winding loop, which is formed by one of the two connecting lines, and a secondary winding having a winding count greater than the number of winding loops of the primary conductor, and a diagnostic device for evaluating an inductance-dependent measurement signal of the secondary winding. The diagnostic device is designed to compare the inductance-dependent measurement signals of the secondary winding to a comparison value, in particular an error threshold value, that can be used to distinguish between the error state and a non-error state of the redundant electrical transmission path.

The invention relates to an electrical system comprising a redundant electrical transmission path and to means for recognizing a defect of the redundant electrical transmission path, as well as to a method for recognizing a defect of the redundant electrical transmission path.

In the case of safety-critical components, it must be ensured that the power supply lines thereof are not interrupted by a line break, faulty plug connections or corrosion. This also applies to safety-critical functions that are triggered by way of a current signal, for example. One example of this is the power supply line for airbags in vehicles or the deployment thereof by means of a current signal that is supplied via a control line.

It is known for these instances to embody the electrical connections redundantly with two electrical lines that run parallel to one another, and to thereby monitor this electrical redundant transmission path in such a way that even the failure of one of the two electrical connections is recognized.

A device and a method for detecting strip conductor interruptions in solar modules are known from EP 0 953 154 A1.

In the case of solar modules that are composed of individual solar cells connected to one another by way of strip conductors, it is possible for interruptions in the strip conductors to occur, which may result in the solar module becoming unusable. For detecting such a strip conductor interruption, it is provided to couple an inductor to a conductor loop that is formed between two adjacent solar cells of the solar module. Together with a capacitor, the inductor forms a tuned circuit, which is excited by means of an alternating current generator. The change of the oscillator properties of the resonant circuit, which is dependent on the impedance of the conductor loop, is detected by means of a measuring transducer coupled to the resonant circuit. With this, the changes of characteristic variables of the resonant circuit which are caused by a strip conductor interruption are indicated by means of the measuring value transducer.

It is the object of the invention to provide an electrical system comprising a redundant electrical transmission path and simple means for recognizing a defect or an error state of the redundant electrical transmission path. It is furthermore the object of the invention to provide a method for recognizing a defect or an error state of the redundant electrical transmission path of the system.

The first object is achieved by an electrical system having the features of claim 1.

Accordingly, an electrical system comprising a first electrical device, a second electrical device, a redundant electrical transmission path including two electrical connecting lines, connected in parallel, between the first electrical device and the second electrical device, and means for recognizing an error state of the redundant electrical transmission path is provided. The means encompass a magnetic core comprising a primary conductor including at least half a winding loop, which is formed by one of the two connecting lines, and including a secondary winding having a number of windings greater than the number of winding loops of the primary conductor. The means furthermore encompass a diagnostic device for evaluating an inductance-dependent measurement signal of the secondary winding, wherein the diagnostic device is designed to compare the inductance-dependent measurement signals (L_{M}) of the secondary winding to an error threshold value that can be used for distinguishing between an error state and a non-error state of the redundant electrical transmission path.

This electrical system thus comprises extremely few, and moreover simple, means for inductively detecting an error state, such as, for example, in the case of a failure of one of the two electrical connecting lines of the redundant electrical transmission path triggered by a line break. A magnetic core comprising a primary conductor, which is formed by one of the two connecting lines, is used as the means. A secondary winding of the magnetic core is inductively coupled to the primary conductor, wherein the primary conductor has only few winding loops, and in the simplest case is a straight section of the connecting line, that is, only represents half a winding loop.

Using these means, the principle of impedance transformation is utilized, wherein preferably the primary conductor can be designed to be very low-resistance, and consequently the transformer formed by the magnetic core together with the primary conductor and the secondary winding does not result in any disadvantageous consequences in the electrical transmission path for the function of the electrical systems. Another advantage is that the two connecting lines do not necessarily have to be energized to recognize an error state, that is, a defect of the redundant electrical transmission path.

The inductance-dependent measurement signal can be generated in a variety of ways, which are known to a person skilled in the art.

It is particularly advantageous when the primary conductor has few winding loops, so that the path via the primary conductor and the secondary winding is influenced as little as possible even in the event of an error, that is, when the error state is present. The winding count of the secondary winding is greater than the number of winding loops of the primary conductor. The higher winding count of the secondary winding reduces the influence of the inductance-dependent measurement signal on the primary winding and the secondary winding, and results in a measurement signal having a favorable signal-to-noise ratio at the secondary winding, which is easy to measure.

The electrical connecting lines of the redundant electrical transmission path are designed as supply lines for supplying energy or are designed as signal lines. The electrical connecting lines can also be designed as switching contacts or as plug or sliding contacts.

The second object is achieved by a method having the features of claim 5.

This method for recognizing an error state of a redundant electrical transmission path comprising two electrical connecting lines, connected in parallel, between a first electrical device and a second electrical device as well as a measuring inductor, which is coupled to at least half a winding loop, which is formed by one of the two connecting lines, according to the first solution comprises the following method steps:
generating an inductance-dependent measurement signal of the measuring inductor;
evaluating the inductance-dependent measurement signal for distinguishing an error state from a non-error state of the redundant electrical transmission path in that the inductance-dependent measurement signal of the measuring inductor is compared to a comparison value, in particular an error threshold value, that can be used to distinguish between an error state and a non-error state of the redundant electrical transmission path;
indicating that a non-error state is present when the inductance-dependent measurement signal is smaller than the comparison value; and
indicating that an error state is present in one of the connecting lines (L1, L2) when the inductance-dependent measurement signal (L_{M}) is greater than the comparison value, that is, in particular the error threshold value.

Even though it is sufficient in most applications to establish an error threshold value as the comparison value, that is, to define a specified constant value that, when exceeded, results in the detection of an error, it is also within the scope of the present invention to use the degree of the change of the measurement signal over time, instead of a fixed threshold value, as a measure for the error detection. If the signal changes too quickly from one measurement to the next, this may likewise be indicative of an error, which can be detected according to the invention. In this way, a creeping, that is, gradual, worsening of the redundant transmission path can advantageously be recognized. With this, a kind of condition monitoring of the redundant transmission path can be carried out.

The method according to the invention can be easily carried out using few means. Initially, an inductance-dependent measurement signal of a measuring inductor is generated, wherein this measuring inductor is a secondary winding that is inductively coupled, by means of a magnetic core, to at least one winding loop formed by one of the two connecting lines, serving as the primary conductor. The inductance-dependent measurement signal of the measuring inductor is evaluated with respect to the presence or the absence of an error state of the redundant electrical transmission path. For this purpose, the comparison value, in particular the error threshold value, is adapted to the manner in which the inductance-dependent measurement signal is generated, so as to be suitable for recognizing a defect, that is, for example, a line break, as the error state of the electrical transmission path by way of comparison to the inductance-dependent measurement signal.

The inductance-dependent measurement signal can be generated in a variety of ways, which are known to a person skilled in the art.

For example, an alternating voltage can be applied to the secondary winding, and from the alternating current generated thereby, serving as the inductance-dependent measurement signal, the reactance can be determined as the comparison value for the comparison to the error threshold value. The comparison value or error threshold value is determined in such a way that, in the case of a non-error state, the comparison value is smaller than this error threshold value and, in the case of an error state, that is, for example, a line break of one of the two lines of the redundant transmission path, the comparison value is greater than this error threshold value.

A low reactance thus indicates that the two lines are intact, that is, redundancy of the electrical transmission path is present. In the case of high reactance, in contrast, a failure, that is, a line break of one of the two connecting lines, is indicated, and redundancy of the electrical transmission is thus not present in this case.

Another method, according to one refinement, for generating the inductance-dependent measurement signal is to determine the attenuation behavior of a low-pass filter or high-pass filter created with the aid of the secondary winding, that is, for example, an RL or LC filter device. From the inductance-dependent measurement signal indicating the attenuation behavior, an attenuation value is ascertained, serving as the comparison value, and is compared to an accordingly suitable error threshold value.

According to another embodiment of the invention, it is possible to create an LC resonant circuit by way of the secondary winding, so that the resonance behavior thereof is indicated by way of the inductance-dependent measurement signal, and from this the resonance frequency is ascertained, serving as the comparison value, so as to be compared to an accordingly suitable error threshold value.

Finally, it is also possible, according to one refinement, to detect and evaluate signal deformations of a control signal, which is applied to the secondary winding and has multiple frequency components, by means of the inductance-dependent measurement signal. In particular, the time curve when switching the secondary winding on and/or off can be detected for this purpose and be evaluated with respect to the build-up events and/or decay events.

The invention is described hereafter in detail based on exemplary embodiments with reference to the accompanying figures. In the drawings:

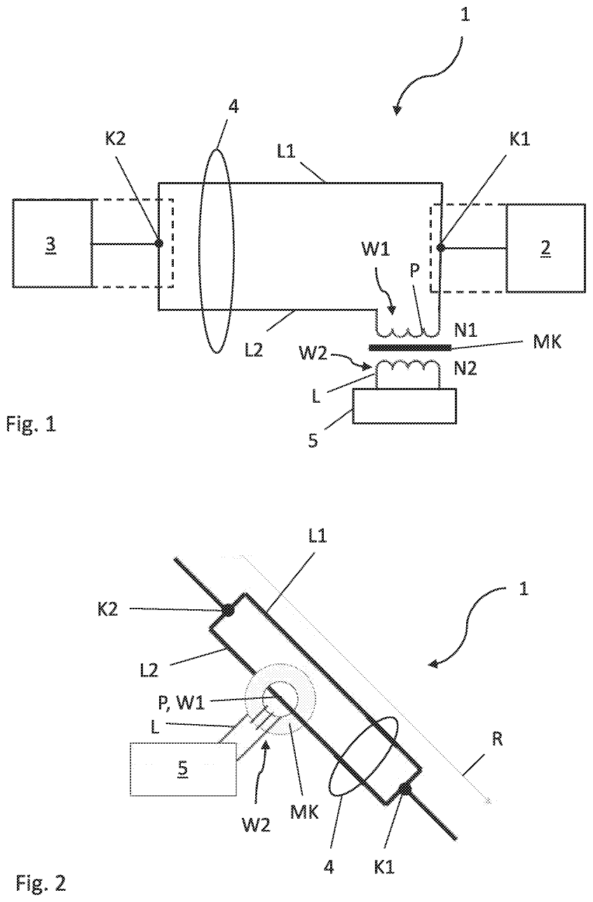

FIG. 1 shows a circuit diagram of an electrical system according to the invention;

FIG. 2 shows a schematic detailed illustration of the magnetic core MK according to FIG. 1; and

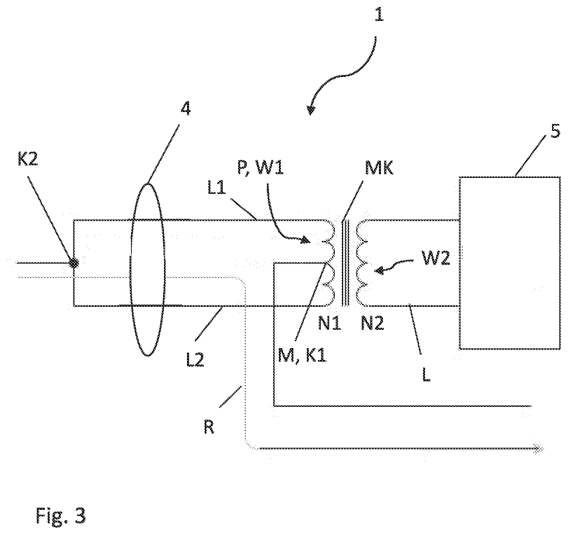

FIG. 3 shows a circuit diagram of a further electrical system according to the invention.

Even though mention is always made of an error threshold value in the following figures and the associated description, it is possible, as explained at the outset, to also use the degree of the change of the measurement signal over time, instead of an error threshold value, for error detection, for example so as to detect creeping changes in the redundant transmission path.

The electrical system 1 according to FIG. 1 comprises a first electrical device 2 and a second electrical device 3, which are electrically connected to one another by means of a redundant electrical transmission path 4. This electrical transmission path 4 is composed of two electrical connecting lines L1 and L2, which are connected in parallel via nodes K1 and K2.

The first electrical device 2 is electrically connected to the node K1, so that this node K1 is situated outside the first electrical device 2. It is also possible for this node K1 to be situated inside the first electrical device 2 (dotted representation of the first electrical device 2).

The second electrical device 3 is electrically connected to the node K2, so that this node K2 is situated outside the second electrical device 3. It is also possible for this node K2 to be situated inside the second electrical device 3 (dotted representation of the second electrical device 3).

For example, the first electrical device 2 is an airbag control unit, and the second electrical device 3 is an airbag module, which is supplied with electrical energy or with a current signal, serving as the deployment signal, via the two connecting lines L1 and L2 of the redundant electrical transmission path 4. In the first case, the two connecting lines L1 and L2 represent power supply lines, and in the second case, they represent signal lines.

The electrical system 1 comprises means by way of which a defect, for example a line break, of one of the two connecting lines L1 or L2 is recognized or detected. Using these means, an error state, that is, a defect, or a non-error state of the electrical transmission path 4 is detected.

These means encompass a magnetic core MK, which comprises a primary conductor P including at least half a winding loop W1 and a secondary winding W2. The primary conductor P is formed by the connecting line L2 and has only few winding loops W1, for example three (N1=3) winding loops W1, while the winding count N2 of the secondary winding W2 is greater than the number N1 of the winding loops W1. Thus, if the number is N1=3, the winding count N2 of the secondary winding W2 is 30, for example.

The secondary winding W2 is inductively strongly coupled to the primary conductor P via the magnetic core MK, as a result of which the inductance of the secondary winding W2 depends on the state of the electrical transmission path 4, that is, whether a defect, this being a line break, of the electrical connecting line L1 and/or of the electrical connecting line L2 is present. The secondary winding W2 is therefore also referred to as a measuring inductor L. The coupling of the secondary winding W2 to the primary conductor P depends on the geometry and the material of the magnetic core MK and on the arrangement of the primary conductor P and the secondary winding W2.

The primary conductor has only few winding loops W1, and in the simplest case, the primary conductor P is only composed of a straight section of the connecting line L2. In this way, it is ensured that the primary conductor P is low-resistance, that is, is in the range of 100 mΩ or less, as a result of which the transformer, which is formed by the magnetic core MK together with the primary conductor P and the secondary winding W2, has no negative influence on the function of the electrical system 1, in particular since the loop impedance of the primary conductor P remains very small in the error-free case of the electrical transmission path 4, that is, when no defect is present.

A diagnostic device 5 is provided as a further means for detecting a defect, for example a line break, of one of the two connecting lines L1 or L2, which is connected to the secondary winding W2, serving as a measuring inductor L, and by way of which an inductance-dependent measurement signal L_{M}, generated by the measuring inductor L, is evaluated for distinguishing between an error state and a non-error state of the redundant electrical transmission path 4. For this purpose, the inductance-dependent measurement signal L_{M} is compared to an error threshold value.

If no defect, that is, the non-error state, of the two electrical connecting lines L1 and L2 is present, that is, if the redundancy of the transmission path 4 is present, the inductance-dependent measurement signal L_{M} indicates low inductance, which is thus smaller than the error threshold value.

If, in contrast, one of the two electrical connecting lines L1 and L2 has a defect, and in particular a line break, as the error state, that is, if the redundancy of the transmission path 4 is not present, high inductance is indicated by the inductance-dependent measurement signal L_{M}, which is thus greater than the error threshold value.

Various methods exist for generating the inductance-dependent measurement signal L_{M}.

A first option for generating an inductance-dependent measurement signal L_{M} is to apply a known alternating voltage to the measuring inductor L, and to evaluate the alternating current generated thereby, serving as the inductance-dependent measurement signal L_{M}. Using the reactance determined from the amplitude and the phase position of the measured alternating current, serving as the comparison value, a comparison is carried out to the error threshold value. If the comparison value is smaller than the error threshold value, a non-error state of the transmission path 4, that is, no line break, is present, while an error state, that is, for example, a line break of one of the two electrical connecting lines L1 or L2 of the transmission path 4, is present in the case of a comparison value that is greater than the error threshold value.

The diagnostic device 5 thus has the quality of indicating the state of the transmission path 4 as a function of the evaluated inductance-dependent measurement signal L_{M}, that is, as to whether a line break is present or is not present, this being either “redundancy is present” or “redundancy is not present”.

Another method for generating the inductance-dependent measurement signal L_{M} is to determine the attenuation behavior of a low-pass filter or high-pass filter created with the aid of the secondary winding W2. An attenuation value, serving as the comparison value, is ascertained from the inductance-dependent measurement signal L_{M} indicating the attenuation behavior and is compared to an accordingly suitable error threshold value.

In the case of an attenuation value that is smaller than the error threshold value, the inductance-dependent measurement signal L_{M} indicates low inductance of the measuring inductor L, that is, a non-error state is present, this being no defect, such as a line break of the transmission path 4. In the other case, this being an attenuation value that is above the error threshold value, the inductance-dependent measurement signal indicates high inductance, that is, an error state is present, this being a defect, such as a line break of the transmission path 4.

A further method for generating the inductance-dependent measurement signal L_{M} involves creating an LC resonant circuit by way of the measuring inductor L, so that the resonant behavior thereof is indicated by way of the inductance-dependent measurement signal L_{M}, and from this the resonance frequency is ascertained, serving as the comparison value, so as to be compared to an accordingly suitable error threshold value.

Finally, it is also possible to detect and evaluate signal deformations of a control signal, which is applied to the measuring inductor L and has multiple frequency components, by means of the inductance-dependent measurement signal L_{M}. In particular, the time curve when switching the secondary winding on and/or off can be detected for this purpose and be evaluated with respect to the build-up events and/or decay events.

This method can, for example, be implemented in such a way that a control signal, in the form of a square wave signal, is applied to the measuring inductor L. The edge profile generated by the control signal is detected as the inductance-dependent measurement signal L_{M}, and the degree of distortion of the edge profile of the control signal is evaluated, since this degree of distortion is dependent on the inductance L_{M} of the measuring inductor L, and thus on the state of the two electrical connecting lines L1 and L2. The degree of distortion, serving as the comparison value, is compared to an appropriate error threshold value.

In the case of a degree of distortion that is smaller than the error threshold value, the inductance-dependent measurement signal L_{M} indicates low inductance of the measuring inductor L, that is, a non-error state is present, this being no defect, such as a line break of the transmission path 4. In the other case, this being a degree of distortion that is above the error threshold value, the inductance-dependent measurement signal indicates high inductance, that is, an error state is present, this being a defect, such as a line break of the transmission path 4.

The state of the two electrical connecting lines L1 and L2 is indicated as a function of the ascertained degree of distortion of the control signal, that is, whether a line break is present or not present, this being either “redundancy is present” or “redundancy is not present”.

FIG. 2 shows an electrical system 1 according to FIG. 1, however without the two electrical devices 2 and 3, with the transformer, which is formed by the magnetic core MK together with the primary conductor P and the secondary winding W2, being shown in a more detailed design. The signaling or power direction of the redundant electrical transmission path 4 is denoted by reference sign R.

According to FIG. 2, the magnetic core MK is designed as a ring core and surrounds the line L2 of the redundant electrical transmission path 4. As a result, the primary conductor P is only made of half a winding loop W1, which thus represents a straight section of the electrical connecting line L1. The secondary winding W2 arranged on the magnetic core MK designed as a ring core is made of a winding count N2 (for example 10 windings) greater than the winding count N1 of the primary conductor P.

FIG. 3 also shows an electrical system according to FIG. 1, however without the two electrical devices 2 and 3. In this FIG. 3 as well, the signaling or power direction of the redundant electrical transmission path 4 is denoted by reference sign R.

The means for recognizing an error state or a non-error state, in this electrical system 1 according to FIG. 3, likewise encompass a magnetic core MK comprising a primary conductor P including multiple winding loops W1 and a secondary winding W2 having a winding count N2 that is greater than the winding count N1 of the primary conductor P, and a diagnostic device 5.

The difference between the electrical system 1 according to FIG. 3 and that according to FIG. 1 is that the two electrical connecting lines L1 and L2 are each connected at the end to a winding end of the winding loops W1, and a center tap M forms the node K1, which is electrically connected to a second electrical device, which is not shown. Corresponding to the electrical system 1 according to FIG. 1, the node K1 is connected to a first electrical device.

### LIST OF REFERENCE SIGNS

1 electrical system
2 first electrical device
3 second electrical device
4 redundant electrical transmission path
5 diagnostic device
K1 node
K2 node
L1 electrical connecting line
L2 electrical connecting line
MK magnetic core
N1 number of winding loops W1
N2 winding count of the secondary winding W2
M center tap of the winding loop W1
P primary conductor
R signaling or power direction
W1 winding loop of the primary conductor P
W2 secondary winding

1. An electrical system (1), comprising:
a first electrical device (2);
a second electrical device (3);
a redundant electrical transmission path (4) comprising two electrical connecting lines (L1, L2), connected in parallel, between the first electrical device (2) and the second electrical device (3); and
means (MK, W1, W2, 5) for recognizing an error state of the redundant electrical transmission path (4), encompassing
a magnetic core (MK) comprising a primary conductor (P) including at least half a winding loop (W1), which is formed by one of the two connecting lines (L1, L2), and a secondary winding (W2) having a winding count (N2) greater than the number (N1) of winding loops (W1) of the primary conductor (P), and
a diagnostic device (5) for evaluating an inductance-dependent measurement signal of the secondary winding (W2),
the diagnostic device (5) being designed to compare the inductance-dependent measurement signals (L_{M}) of the secondary winding (W2) to a comparison value, in particular an error threshold value, that can be used to distinguish between the error state and a non-error state of the redundant electrical transmission path (4).

2. The electrical system (1) according to claim 1, wherein the primary conductor (P) is designed to be lower resistance than the secondary winding (W2).

3. The electrical system (1) according to claim 1, wherein the connecting lines (L1, L2) are designed as supply lines for supplying energy.

4. The electrical system (1) according to claim 1, wherein the connecting lines (L1,L2) are designed as signal lines.

5. The electrical system according to claim 1, wherein the comparison value is a measure of the change of the measurement signal over time.

6. A method for recognizing an error state of a redundant electrical transmission path (4) comprising two electrical connecting lines (L1, L2), connected in parallel, between a first electrical device (2) and a second electrical device (3) as well as a measuring inductor (L), which is inductively coupled to at least half a winding loop (W1), which is formed by one of the two connecting lines (L1, L2), comprising the following method steps:
generating an inductance-dependent measurement signal (L_{M}) of the measuring inductor (L);
evaluating the inductance-dependent measurement signal (L_{M}) for distinguishing an error state from a non-error state of the redundant electrical transmission path (4) in that the inductance-dependent measurement signal (L_{M}) of the measuring inductor (L) is compared to a comparison value, in particular an error threshold value, that can be used to distinguish between an error state and a non-error state of the redundant electrical transmission path (4);
indicating that a non-error state is present when the inductance-dependent measurement signal (L_{M}) (L_{M}) is smaller than the comparison value; and
indicating that an error state is present in one of the connecting lines (L1, L2) when the inductance-dependent measurement signal (L_{M}) (L_{M}) is greater than the comparison value.

7. The method according to claim 5, wherein an attenuation value of an RL low-pass filter or RL high-pass filter or LC filter, which is formed by means of the secondary winding (W2), is ascertained as the inductance-dependent measurement signal (L_{M}).

8. The method according to claim 5, wherein a resonance frequency of a resonant circuit, which is formed by means of the secondary winding (W2), is ascertained as the inductance-dependent measurement signal (L_{M}).

9. The method according to claim 5, wherein the signal deformation of a control signal, which is applied to the secondary winding (W2) and has a plurality of frequency components, is ascertained as the inductance-dependent measurement signal (L_{M}).
